(19) United States
(12) Patent Application Publication
(10) Pub. No.: US 2025/0017057 A1
(43) Pub. Date: Jan. 9, 2025

(54) DISPLAY DEVICE

(71) Applicant: Samsung Display Co., LTD., Yongin-si (KR)

(72) Inventors: DOOSUB CHOI, Yongin-si (KR); Byung Sik KOH, Yongin-si (KR); KYUNGBUM KIM, Yongin-si (KR); CHEOLHWAN EOM, Yongin-si (KR)

(73) Assignee: Samsung Display Co., LTD., Yongin-si (KR)

(21) Appl. No.: 18/440,420

(22) Filed: Feb. 13, 2024

(30) Foreign Application Priority Data
Jul. 3, 2023 (KR) 10-2023-0085939

(51) Int. Cl. H10K 59/126; H10K 59/65; H10K 59/80

(52) U.S. Cl. CPC H10K 59/126; H10K 59/65; H10K 59/8791

(57) ABSTRACT

A display device according to an embodiment includes a first conductive plate, a lower protective film positioned on the first conductive plate, a display panel positioned on the lower protective film, a cover window positioned on the display panel, and a voltage application part that applies a compensation voltage to the cover window, wherein the compensation voltage has a same polarity as charges accumulated in case that an external object rubs against the outer surface of the cover window.

### CROSS-REFERENCE TO RELATED APPLICATION

This application claims priority to and the benefit of Korean Patent Application No. 10-2023-0085939 under 35 U.S.C. § 119, filed at the Korean Intellectual Property Office (KIPO) on Jul. 3, 2023, the entire contents of which are incorporated herein by reference.

### BACKGROUND

### 1. Technical Field

The disclosure relates to a display device.

### 2. Description of the Related Art

Display devices such as a liquid crystal display (LCD) and an organic light emitting diode display (OLED display) include a display panel including one or more pixels and one or more signal lines capable of displaying an image, and the display device includes a cover window to protect the panel.

Each pixel includes a pixel electrode to which a data signal is applied, and the pixel electrode is connected to at least one transistor to receive a data signal.

The display panel may include a display area that is capable of displaying an image and a peripheral area around the display area.

The cover window covers the display panel.

Light of an image displayed on the display panel may pass through a cover window on the display area and be recognized by the user's eyes.

### SUMMARY

The cover window of the display device is charged by an object in contact with the cover window, and characteristics of transistors of the display panel may change due to the induced charge.

Embodiments are intended to solve such problems by reducing the impact on the transistors of the display panel caused by the charges applied to the cover window of the display device, thereby reducing display defects.

The technical objectives to be achieved by the disclosure are not limited to those described herein, and other technical objectives that are not mentioned herein would be clearly understood by a person skilled in the art from the description of the disclosure.

A display device according to an embodiment includes a first conductive plate, a lower protective film positioned on the first conductive plate, a display panel positioned on the lower protective film, a cover window positioned on the display panel, and a voltage applicator that applies a compensation voltage to the cover window, wherein the compensation voltage has a same polarity as charges accumulated in case that an external object rubs against the outer surface of the cover window.

The display device may further include a driving part that applies a voltage to the display panel, and a conductive adhesive layer positioned between the driving part and the first conductive plate, and electrically connecting the driving part to the first conductive plate. The voltage application part may be located in the driving part.

The display device may further include a wire formed in the driving part and electrically connecting the voltage application part and the conductive adhesive layer.

The display panel may include a display area, a driving part area, and a bending area positioned between the display area and the driving part area, and the display panel may be bent in the bending area so that the driving part area overlaps a rear surface of the display panel, and the driving part may be mounted in the region of the driving part and electrically connected to the driving part.

The driving part may include a flexible printed circuit film, a printed circuit board, or at least one driving circuit chip.

A polarity of the temporal average of the compensation voltage may be the same as a polarity of charges accumulated on an outer surface of the cover window.

An absolute value of the temporal average of the compensation voltage may be greater than or equal to an absolute value of a potential of charges accumulated on the outer surface of the cover window.

The compensation voltage may be constant.

The compensation voltage may swing between two voltages.

The adhesive layer may further include an adhesive layer disposed between at least one of the first conductive plate and the lower protective film, between the lower protective film and the display panel, and between the display panel and the cover window.

The display device may further include a polarizer positioned between the display panel and the cover window.

An ink layer may be positioned on an inner or outer edge of the display panel, and the ink layer may be non-conductive or have a resistance of about 1 ohm or more.

The display panel may further include a sensing area overlapping at least one optical element, the display panel having an inner edge defining the sensing area, and the ink layer including a first ink layer formed along the inner edge.

The display panel may have three outer edges, and the ink layer may include a second ink layer formed along at least a part of the three outer edges.

The display device may further include a second plate positioned below the first conductive plate and having an opening exposing the first conductive plate, and a conductive adhesive layer positioned in the opening and electrically connected to the first conductive plate.

The display device may further include a second plate positioned between the first conductive plate and the lower protective film.

A display device according to an embodiment includes a first conductive plate, a lower protective film on the first conductive plate, a display panel on the lower protective film, a cover window on the display panel and the first conductive plate, and a voltage application part that applies a compensation voltage to the compensation voltage, and an average of the compensation voltage is about-1 V or less.

The compensation voltage may be constant or swing between two voltages.

The display device may further include a driving part that applies a voltage to the display panel, and a conductive adhesive layer positioned between the driving part and the first conductive plate, and electrically connecting the driving part to the first conductive plate. The voltage application part may be located in the driving part.

The display panel may include a display area, a driving part area, and a bending area positioned between the display area and the driving part area, the display panel may be bent in the bending area so that the driving part area overlaps a rear surface of the display panel, and the driving part may be mounted in the region of the driving part and electrically connected to the driving part.

According to embodiments, display defects may be reduced by reducing an effect on transistors of a display panel by charges charged in a cover window of a display device.

### BRIEF DESCRIPTION OF THE DRAWINGS

FIG. 1 is a schematic plan view of a front surface of a display device according to an embodiment.

FIG. 2 is a schematic plan view of a rear surface of a display device according to an embodiment.

FIG. 3 is a schematic cross-sectional view of the display device shown in FIG. 2 taken along line A1-B1.

FIG. 4 is a schematic cross-sectional view of the display device shown in FIG. 2 taken along line A2-B2.

FIG. 5 is a schematic graph of a potential obtained by measuring a surface potential of a cover window after an external object contacts the cover window of a display device according to an embodiment.

FIG. 6 shows a schematic cross-sectional view of a display device according to an embodiment and strength of an electric field applied to a transistor.

FIG. 7 shows a c schematic ross-sectional view of a display device according to a comparative example and the strength of an electric field applied to a transistor,

FIG. 8 is a schematic graph showing a change in characteristics of a transistor according to an increase in potential due to charge induced in a display panel of a display device according to a comparative example.

FIG. 9 is a schematic cross-sectional view of the display device shown in FIG. 2 taken along line A3-B3.

FIG. 10 is a schematic plan view of a rear surface of a display device according to an embodiment.

FIG. 11 is a schematic cross-sectional view of the display device shown in FIG. 10 taken along line A1-B1.

FIG. 12 is a schematic cross-sectional view of the display device shown in FIG. 10 taken along line A2-B2.

FIG. 13 is a schematic cross-sectional view of the display device shown in FIG. 2 taken along line A1-B1.

FIG. 14 is a schematic cross-sectional view of the display device shown in FIG. 2 taken along line A3-B3.

FIG. 15 is a schematic cross-sectional view of the display device shown in FIG. 2 taken along line A1-B1.

FIG. 16 is a schematic cross-sectional view of the display device shown in FIG. 2 taken along line A3-B3.

### DETAILED DESCRIPTION OF THE EMBODIMENTS

Hereinafter, various embodiments of the disclosure will be described in detail with reference to the accompanying drawings so that those skilled in the art can carry out the disclosure.

This disclosure may be embodied in many different forms, and is not limited to the embodiments set forth herein.

In order to more clearly describe the disclosure, parts irrelevant to the description may be omitted, and the same reference numerals may be assigned to the same or similar components throughout the specification.

Since the size and thickness of each component shown in the drawings may be arbitrarily shown for convenience of explanation, the disclosure is not necessarily limited to that which is shown.

In the drawings, the thickness may be shown enlarged to clearly express the various layers and regions. In other words, for convenience of explanation, the thicknesses of some layers and regions are exaggerated.

When a part such as a layer, film, region, or plate is said to be “above” or “on” another part, this includes not only the case where it is “directly on” the other part, but also the case where another part is in the middle. Conversely, when a part is said to be “directly on” another part, it means that there is no other part in between. In addition, being “above” or “on” a reference part means being located above or below the reference part, and does not necessarily mean being located “above” or “on” it in the opposite direction of gravity.

In addition, throughout the specification, when a certain component is said to “include,” “comprise,” or “have,” it means that it may further include, comprise, or have other components without excluding other components unless otherwise stated.

Throughout the specification, when reference is made to a “planar image” or “plan view,” it means when the target part is viewed from above, and when reference is made to a “cross-sectional image” or “cross-sectional view,” it means when the cross-section of the target part cut vertically is viewed from the side.

When an element is referred to as being “on,” “connected to,” or “coupled to” another element, it may be directly on, connected to, or coupled to the other element or intervening elements or layers may be present. When, however, an element is referred to as being “directly on,” “directly connected to,” or “directly coupled to” another element, there are no intervening elements or layers present. To this end, the term “connected” may refer to physical, electrical, and/or fluid connection, with or without intervening elements.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

The term “and/or” includes all combinations of one or more of which associated configurations may define. For example, “A and/or B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

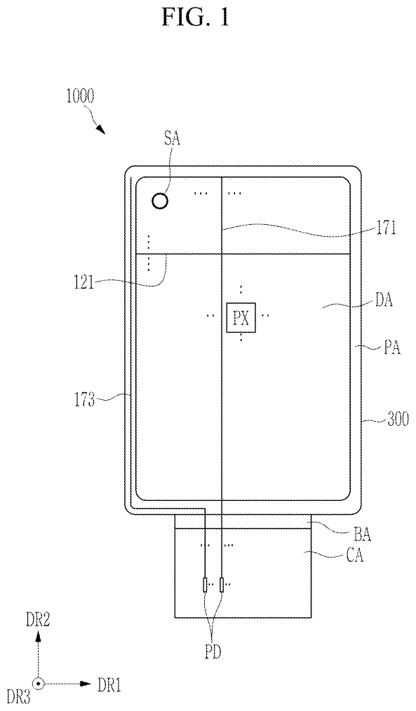

A display device according to an embodiment will be described with reference to FIG. 1 to FIG. 5.

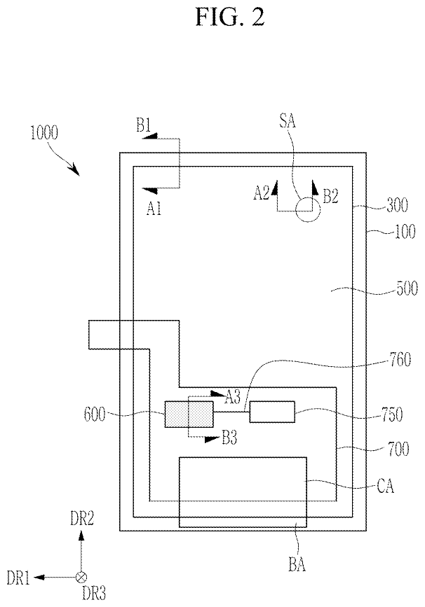

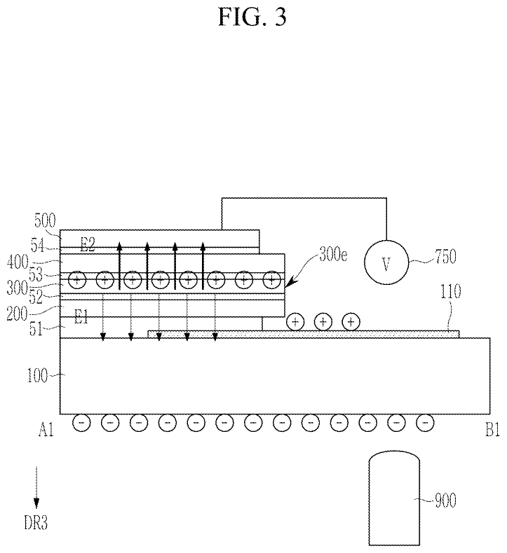

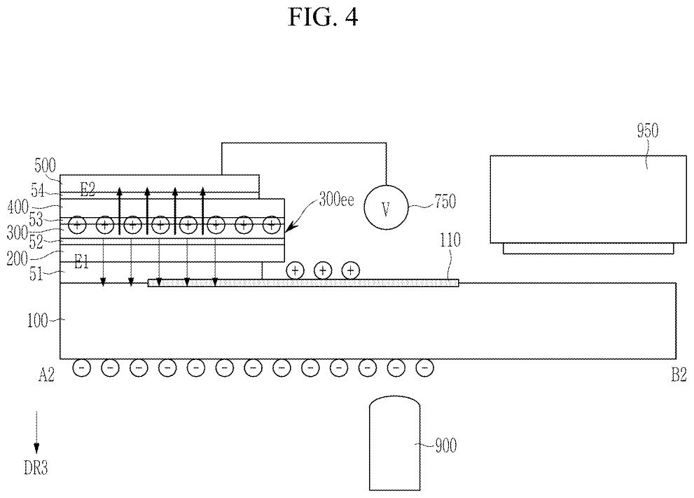

FIG. 1 is a schematic plan view of the front of a display device according to an embodiment, FIG. 2 is a schematic plan view of the rear side of the display device according to an embodiment, and FIG. 3 is a schematic cross-sectional view of the display device shown in FIG. 2 along line A1-B1. FIG. 4 is a schematic cross-sectional view of the display device shown in FIG. 2 cut along line A2-B2.

Referring to FIG. 1, a display device 1000 according to an embodiment includes a display panel 300 including a display area DA, which is an area capable of displaying an image, and a non-display area, which is an area excluding the display area DA.

The display area DA may display an image. For example, the display area DA may display an image on a plane parallel to the first and second directions DR1 and DR2. However, the embodiments are not limited thereto. In another embodiment, for example, the plane may be defined in a various ways within the scope and spirit of the disclosure.

The display area DA may include pixels PX as a unit for displaying an image and one or more signal lines.

The pixel PX may include at least one transistor formed on a substrate and a pixel electrode connected thereto.

For example, in case that the pixel PX includes at least one light emitting device, each pixel PX may include at least one transistor connected to the light emitting device.

In order to implement color display, each pixel PX can display one of specific colors, and an image of a desired color can be recognized as the sum of images displayed by these specific colors.

The signal lines include scan lines 121 for transmitting scan signals and one or more data lines 171 for transmitting data signals.

In an embodiment, each scan line 121 can be extended primarily in the first direction DR1 in the display area DA, and the data line 171 can be extended primarily in the second direction DR2 in the display area DA and can be connected to a pad PD located in the non-display area. However, the embodiments are not limited thereto. For example, the scan lines 121 and data lines 171 may extend in different directions, and/or the pad PD may be located in the display area and/or non-display area.

The non-display area may include a peripheral area PA located around the display area DA and a driving part area CA.

The peripheral area PA may be an area adjacent to the display area DA and surrounding the display area DA.

At least one signal line 173 may be located in the peripheral area PA.

The signal line 173 may extend along the edge of the display area DA and extend to the driving part area CA.

The display panel 300 according to an embodiment may further include a bending area BA.

The bending area BA may be positioned between the driving part area CA and the display area DA, and may extend across the display panel 300, e.g., in the first direction DR1.

The display panel 300 is bent in the bending area BA so that the driving part area CA positioned outside the bending area BA is folded toward the back of the display panel 300 and overlaps the rear surface of the display panel 300. It may overlap a part of the display area DA.

FIG. 1 shows a state in which the display panel 300 is unfolded without being bent in the bending area BA, and FIG. 2 shows a state in which the bending area BA is bent so that the driving part area CA is located on the rear surface of the display panel 300, a state of overlapping the rear surface of the display panel 300.

The bending area BA may be omitted depending on the structure of the display device.

Referring to FIG. 1, the driving part area CA may be located below the lower side of the display area DA and outside the bending area BA.

The driving part area CA may include one or more pads PD.

Referring to FIG. 2, at least one driving part 700 may be mounted in the driving part area CA, and may be electrically connected to the pad PD.

The driving part 700 may apply various driving signals, driving voltages, or the like to the display area DA and the peripheral area PA of the display device 1000.

The driving part 700 may be in the form of a flexible printed circuit film, a printed circuit board, or at least one driving circuit chip.

FIG. 2 shows an example in which the driving part 700 is a flexible printed circuit film or a printed circuit board.

The data lines 171 may be connected to the driving part 700 to receive data signals.

The display panel 300 may further include one or more touch sensors located in the display area DA.

The touch sensor may include one or more sensing electrodes.

Referring to FIG. 1, FIG. 2, and FIG. 4, the display area DA of the display device 1000 according to an embodiment may include a sensing area SA.

Also, the display device 1000 according to an embodiment may further include at least one optical element 950 overlapping the sensing area SA, e.g., in the third direction DR3.

The sensing area SA may be an area where light is incident to or emitted from the optical element 950.

The optical element 950 may include a camera, flash, sensor, or the like.

For example, the optical element 950 may emit light in a wavelength range (e.g., a certain or selectable wavelength range) toward an object located on the display device 1000 or receive light reflected from the object.

The light of a wavelength (e.g., a certain or selectable wavelength) can be light of a wavelength other than the visible light region, which is the light of the image displayed in the display area DA, and can be processed in the optical device 950; it can also be light of the visible light region, similar to the light of the image displayed in the display area DA.

The sensing area SA may have higher light transmittance than the surrounding display area DA and the peripheral area PA.

Light emitted from or incident to the optical device 950 may pass through the sensing area SA of the display device 1000.

As shown in FIG. 1, the sensing area SA may be located adjacent to the top or an area around the top of the display area DA, but the location of the sensing area SA is not limited thereto. For example, the sensing area SA may be located in a selected area of the display area DA.

Referring to FIG. 3, the display panel 300 may include an outer edge 300e forming an outline, and referring to FIG. 4, the display panel 300 may include an inner edge defining the outer edge of the sensing area SA (300ee).

An optical element 950 may be disposed in a sensing area surrounded by an inner edge 300ee of the display panel 300.

A cross-sectional structure of a display device according to an embodiment will be described with reference to FIG. 3 and FIG. 4 along with FIG. 1 and FIG. 2.

Referring to FIG. 3 and FIG. 4, the display device according to an embodiment may include a cover window 100, a polarizer 200, a display panel 300, and/or a lower protective film 400 overlapping, e.g., in a third direction DR3, and may include a lower plate (500).

As described above, the display panel 300 may include one or more pixels and one or more transistors, and may be a display panel of various display devices such as a liquid crystal display device and an organic light emitting display device.

The display panel 300 may display an image toward the cover window 100.

In an embodiment illustrated in FIG. 3 and FIG. 4, the direction in which images are displayed may be the same as the third direction DR3.

The cover window 100 may form an outer surface of a surface displaying an image of the display device, and may come into contact with an external object.

Depending on the embodiment, at least one upper protective film may be further positioned outside the cover window 100.

The upper protective film may include a polymer resin.

The cover window 100 may transmit an image provided by the display area DA of the display panel 300 and may include a light blocking member 110 overlapping at least a portion of the peripheral area PA.

The light blocking member 110 may be formed on the rear surface of the cover window 100 facing the display panel 300.

The cover window 100 may include an insulating material such as glass, sapphire, or polymer resin.

The polarizer 200 may be positioned between the display panel 300 and the cover window 100.

The polarizer 200 may serve to reduce external light reflection.

In an embodiment, the polarizer 200 may be in the form of a polarizing film. However, the embodiments are not limited thereto. For example, the polarizer 200 may be in various forms within the scope of spirit of the disclosure.

The polarizer 200 may include at least one polarization layer and/or at least one retardation layer.

The polarization layer may include polyvinyl alcohol (PVA) and may further include at least one support.

For example, the polarizer 200 may be a circularly polarized film.

An adhesive layer 51 may be positioned between the cover window 100 and the polarizer 200.

An adhesive layer 52 may be positioned between the polarizer 200 and the display panel 300.

The lower plate 500 positioned on the opposite side of the cover window 100 with respect to the display panel 300 may be conductive and may include, for example, various metals or metal alloys.

A lower protective film 400 may be positioned between the display panel 300 and the lower plate 500.

The lower protective film 400 may include, e.g., polyethylene terephthalate (PET), poly(butylene terephthalate) (PBT), polycarbonate (PC), polyethylene naphthalate (PEN), polystyrene (polystyrene, PS), polymethylmethacrylate (PMMA), polyvinylchloride (PVC), polyethersulfone (PES), polypropylene (PP), and polyamide (PA) and may include at least one of polymer resins.

An adhesive layer 53 may be positioned between the display panel 300 and the lower protective film 400.

An adhesive layer 54 may be positioned between the lower protective film 400 and the lower plate 500.

At least one of the adhesive layers 51, 52, 53, and 54 may include a polymeric organic material, and may be a thermosetting type or a UV curing type.

For example, the adhesive layers 51, 52, 53, and 54 may include a polymer resin such as an acrylic material, a silicon material, rubber, polyurethane, vinyl acetate, an epoxy resin, or styrene-butadiene-styrene (SBS).

In particular, the adhesive layers 51 and 52 positioned between the display panel 300 and the cover window 100 may be optically transparent adhesive layers, such as optically clear adhesive (OCA), optically clear resin (OCR), or pressure-sensitive adhesive (PSA).

Referring to FIG. 2 to FIG. 4, the cover window 100 may cover the layers below it—for example, the polarizer 200, the display panel 300, the lower protective film 400, and the lower plate 500—and it can cover these layers by having a larger area than these layers on a plane.

The light blocking member 110 of the cover window 100 may overlap edges of the polarizer 200, the display panel 300, the lower protective film 400, and/or the lower plate 500.

Referring to FIG. 3 and FIG. 4, in case that an external object 900 such as a stylus pen touches or rubs against an outer surface of the cover window 100, the cover window 100 may be charged with static electricity.

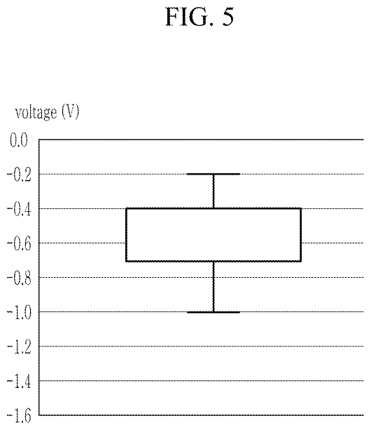

FIG. 5 is a graph of the potential measured on the surface of the cover window of a display device according to an embodiment, after contact with an external object; it is a result graph of measuring the surface potential of the cover window after roughly rubbing the outer surface of the cover window with an external object about 675 times over a period of about 12 hours.

Referring to FIG. 5, after a test of rubbing an external object such as a stylus pen on the outer surface of the cover window for several hours (for example, 12 hours), it can be confirmed that the surface potential of the outer side of the cover window is distributed from about −0.2 V to about −1.0 V broadly, and mostly falls within a range of about −0.4 V to about −0.7 V narrowly.

For example, negative charges forming a potential in a range of about −1 V to about 0 V are accumulated on the outer surface of the cover window 100 due to contact with an external object.

Referring to FIG. 3 and FIG. 4, in case that a negative static charge accumulates on the outer surface of the cover window 100, a positive charge may be induced on the inner surface opposite to the outer surface of the cover window (100) or the light-blocking member 110, and on the substrate side of the display panel 300.

Then, an electric field E1 may be formed from the substrate side of the display panel 300 toward the cover window 100, which may affect the characteristics of the transistors of the display panel 300.

The polarity of frictional charges accumulated on the outer surface of the cover window 100 is not limited to negative charges, and may vary depending on the material of the cover window 100 and the material of the external object 900.

A constant or varying compensation voltage may be applied to the lower plate 500 of the display device according to an embodiment.

To this end, the display device according to an embodiment may include a voltage application part 750 for applying a compensation voltage to the lower plate 500.

The voltage application part 750 may be located in the driving part 700 as shown in FIG. 2.

The absolute value of the temporal average of the compensation voltage may be greater than or equal to the absolute value of the potential of charges accumulated on the outer surface of the cover window 100.

The polarity of the temporal average of potentials of the compensation voltage may be substantially the same as the polarity of charges accumulated on the outer surface of the cover window 100.

In case that a constant compensation voltage is applied to the lower plate 500, a voltage having the same polarity as the charge accumulated on the outer surface of the cover window 100 may be applied.

The absolute value of the compensation voltage applied to the lower plate 500 by the voltage application part 750 may be equal to or greater than the absolute value of the voltage due to charges accumulated on the outer surface of the cover window 100.

For example, as described above, since the maximum value of the absolute value of the voltage due to the charges accumulated on the outer surface of the cover window 100 may be approximately 1 V, the voltage application part 750 may apply compensation to the lower plate 500. The absolute value of the voltage may be greater than or equal to 1 V, and in case that the charge accumulated on the outer surface of the cover window 100 is negative, the compensation voltage may be, for example, a voltage between about −1 V and about −5 V.

In case that a varying compensation voltage is applied to the lower plate 500, the compensation voltage may be a voltage that swings between two voltages.

The polarity of the average of the maximum and minimum values of the swinging voltage may be substantially the same as the polarity of the charge accumulated on the outer surface of the cover window 100.

The absolute value of the average of the maximum and minimum values of the swinging voltage may be equal to or greater than the absolute value of the electric potential due to the charge accumulated on the outer surface of the cover window 100.

For example, as described above, in case that the minimum value of the voltage due to the charges accumulated on the outer surface of the cover window 100 is about −1 V, the voltage application part 750 may apply swing compensation to the lower plate 500. The average of the maximum and minimum values of the voltage may be equal to or less than about −1 V.

For a more specific example, the compensation voltage applied to the lower plate 500 by the voltage application part 750 may swing between about −1 V and about −5 V or between about −2 V and about 0 V.

Even in this case, the absolute value of the average of the swinging compensation voltages applied to the lower plate 500 by the voltage application part 750 may be equal to or greater than the absolute value of the potential due to the charge accumulated on the outer surface of the cover window 100.

According to an embodiment, an opposite electric field E2 may be formed from the substrate side of the display panel 300 toward the lower plate 500 by the compensation voltage applied to the lower plate 500, as shown in FIG. 3 and FIG. 4.

For example, the amount of positive charges induced on the substrate side of the display panel 300 by the negative charges applied to the lower plate 500 is reduced, thereby reducing the effect on the characteristics of the transistors of the display panel 300.

As shown in FIG. 3 and FIG. 4, an electric field E1 caused by charges on the substrate of the display panel 300 induced by negative charges accumulated on the outer surface of the cover window 100 may be applied to the lower plate 500, since the effect of the electric field on the transistors of the display panel 300 is reduced by being canceled or reduced by the opposite electric field E2 formed by the compensation voltage, the change in characteristics of the transistors may be reduced.

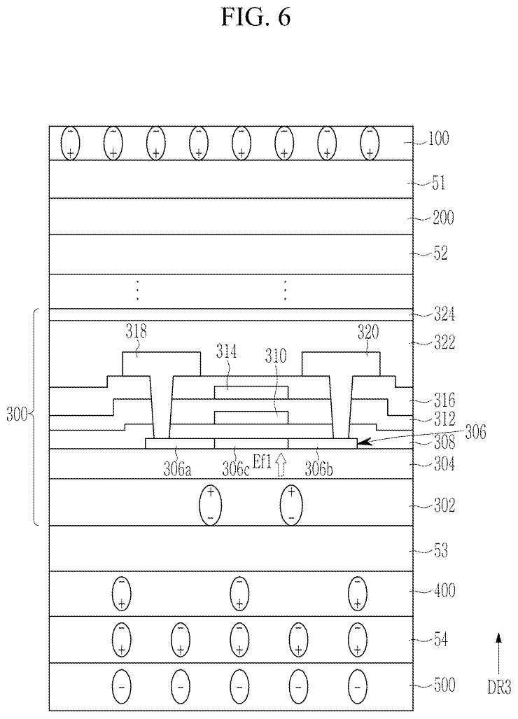

This will be described in detail with reference to FIG. 6 to FIG. 8.

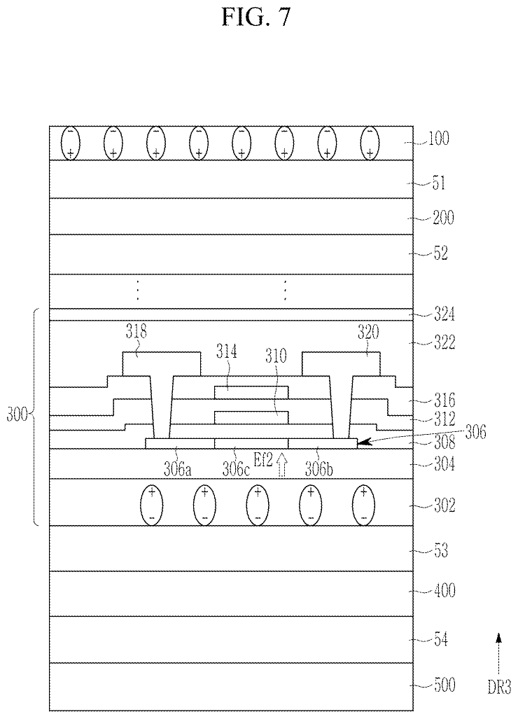

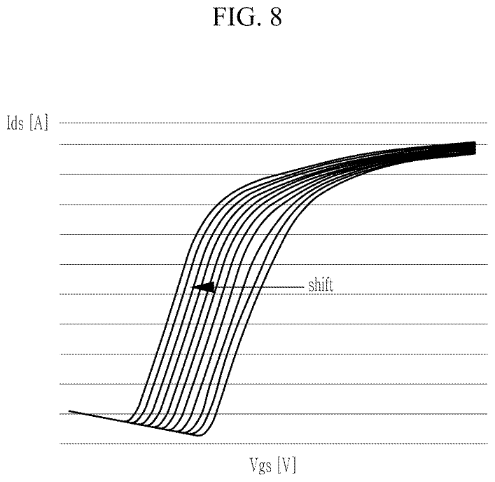

FIG. 6 illustrates a schematic cross-sectional view of a display device according to an embodiment and the strength of an electric field affecting the transistor, FIG. 7 illustrates a schematic cross-sectional view of a display device according to a comparative example and the strength of an electric field affecting the transistor, and FIG. 8 is a schematic graph showing the characteristic change of the transistor due to the increase in potential caused by the charge induced on the display panel of the display device according to a comparative example.

Referring to FIG. 6, a display panel 300 of a display device according to an embodiment may include a substrate 302.

The substrate 302 may include an insulating material such as glass or polyimide.

A buffer layer 304, a semiconductor layer 306, a first insulating layer 308, a first conductive layer 310, a second insulating layer 312, and/or a second insulating layer 308 may be formed on the substrate 302 in the third direction DR3. The conductive layer 314, the third insulating layer 316, the third conductive layers 318 and 320, the fourth insulating layer 322, and the light emitting device 324 may be sequentially positioned.

In an embodiment, the buffer layer 304, the first insulating layer 308, the second insulating layer 312, and/or the third insulating layer 316 may include, e.g., an organic insulating material and/or an inorganic insulating material, such as silicon oxide (SiOₓ), silicon nitride (SiNₓ), silicon oxynitride (SiOₓN_{y}),.

The semiconductor layer 306 may include an oxide semiconductor, an amorphous silicon, a polycrystalline silicon, or the like.

In an embodiment, a portion of the semiconductor layer 306 may include impurities to form a conductive region, and a portion of the semiconductor layer 306 may form a channel region.

FIG. 6 shows an example in which the semiconductor layer 306 includes a channel region 306c, and conductive regions 306a and 306b positioned on both sides of the channel region 306c.

The first conductive layer 310 may include a gate electrode overlapping the channel region 306c of the semiconductor layer 306.

The gate electrode of the first conductive layer 310 and the semiconductor layer 306 may form a transistor together.

The second conductive layer 314 may overlap at least a portion of the first conductive layer 310 to form a capacitor.

A voltage different from that of the gate electrode may be applied to the second conductive layer 314.

The third conductive layer (318, 320) may include a connection electrode 318 electrically connected to the conductive region 306a of the semiconductor layer 306, and a connection electrode 320 electrically connected to the conductive region 306b of the semiconductor layer 306.

The first conductive layer 310, the second conductive layer 314, and the third conductive layers 318 and 320 may include, e.g., at least one metal or metal alloy including aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), Titanium (Ti), tungsten (W), or copper (Cu), and/or may be composed of a single layer or multiple layers.

The fourth insulating layer 322 may include an organic insulating material such as a polymer derivative, acrylic polymer, imide polymer, polyimide, polyamide, acrylic polymer, or siloxane polymer, or an inorganic insulating material.

The light emitting device 324 may be formed on the fourth insulating layer 322 or a separately formed light emitting device may be mounted on the fourth insulating layer 322.

The light emitting device 324 may include two electrodes and a light emitting layer positioned between the two electrodes.

The light emitting device 324 may emit light toward the cover window 100.

Although not shown in FIG. 6, at least one insulating layer may be further positioned on the light emitting device 324.

Referring to FIG. 6, as described above, in case that negative static charges are accumulated on the outer surface of the cover window 100, the inner surface opposite to the outer surface of the cover window 100 and the substrate 302 of the display panel 300, a positive charge may be induced on a side, especially on the top side of the substrate 302 facing the transistor.

However, according to an embodiment, in case that a compensation voltage is applied to the lower plate 500 and charges of the same polarity as the charges induced on the outer surface of the cover window 100 are introduced, the layer between the substrate 302 and the lower plate 500 may be introduced. In this case, positive charges induced on the top surface of the substrate 302 of the display panel 300 may be offset and disappear, or only partially remain.

As a result, the electric field Ef1 that finally affects the transistors of the display panel 300 may be reduced, so that the change in characteristics of the transistors caused by the electric field can be reduced.

FIG. 6 shows a state in which the electric field Ef1 may be very small because only a portion of the positive charge on the upper surface of the substrate 302 of the display panel 300 remains.

On the other hand, referring to FIG. 7 for comparison, the display device according to a comparative example may be distinguishable from the display device shown in FIG. 6 at least in that a compensation voltage of the same polarity is not applied to the charge transferred to the outer surface of the cover window 100 on the lower plate 500.

According to this, the positive charge induced on the upper surface of the substrate 302 of the display panel 300 remains as it is, and the change in characteristics of the transistor increases while the electric field Ef2 finally affecting the transistor of the display panel 300 increases.

The intensity of the electric field Ef2 shown in FIG. 7 may be greater than the intensity of the electric field Ef1 shown in FIG. 6.

As illustrated in FIG. 8, the current (Ids) versus voltage (Vgs) curve (I-V curve) of the transistor's gate and source tends to shift left—i.e., in the direction of the horizontal arrow—as the strength of the induced charge or the electric field (Ef1, Ef2) on the top surface of the display panel's substrate (302) increases.

According to an embodiment, since the intensity of the electric field may be weakened, the I-V curve of the transistor may not shift or the degree of shift may be reduced so that the change in characteristics of the transistor is reduced.

In case that the shift of the I-V curve of the transistor increases, the current Ids of the transistor may increase so that the display screen at the edge of the sensing area SA becomes bright and can be recognized as a stain.

However, according to an embodiment, since the degree of shift of the I-V curve of the transistor of the display panel may be reduced, it is possible to prevent occurrence of display defects, such as spots caused by brightening of the display screen at the edge of the sensing area SA.

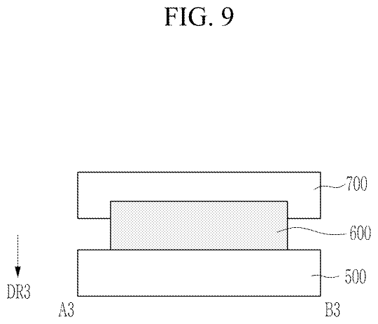

A structure of a display device according to an embodiment will be described with reference to FIG. 9 together with FIG. 2 described above.

FIG. 9 is a schematic cross-sectional view of the display device shown in FIG. 2 taken along line A3-B3.

Referring to FIG. 9 together with FIG. 2, the driving part 700 may be electrically connected to the lower plate 500 through the conductive adhesive layer 600, and the voltage application part 750 located in the driving part 700 may be electrically connected to the conductive adhesive layer 600 through the wiring 760.

The wiring 760 may be formed in the driving part 700.

The conductive adhesive layer 600 may include an adhesive material such as conductive PSA, may be in the form of a conductive film, or may include conductive balls, depending on embodiments.

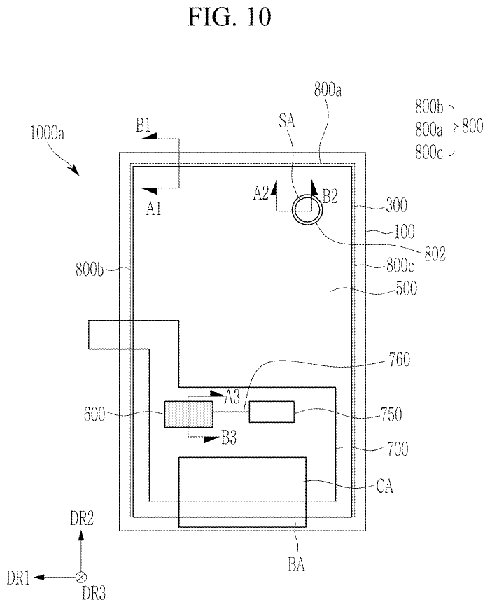

A display device according to an embodiment will be described with reference to FIG. 10 to FIG. 12 together with the previously described drawings.

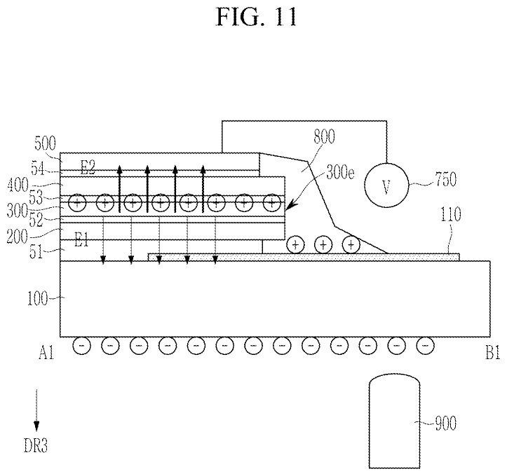

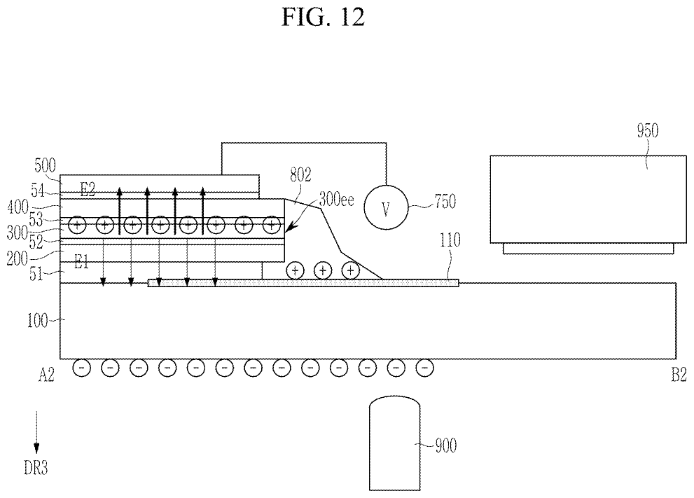

FIG. 10 is a schematic plan view of the rear surface of a display device according to an embodiment, FIG. 11 is a schematic cross-sectional view of the display device shown in FIG. 10 taken along line A1-B1, and FIG. 12, a view of the display device shown in FIG. 10, is a schematic cross-sectional view cut along line A2-B2.

The display device 1000a according to an embodiment may be distinguishable from the display device 1000 described above at least in that the display device 1000a may further include ink layers 800 and 802 positioned at inner or outer edges of the display panel 300.

The ink layer 800 located on the outer edge of the display panel 300 may be formed along at least some of the outer edges of the three surfaces of the display panel 300, excluding the side where the driver area CA is located.

FIG. 10 illustrates an example in which the ink layer 800 includes a first ink layer 800a, a second ink layer 800b, and a third ink layer 800c formed along different outer edges of the display panel 300.

The first ink layer 800a may be formed along the outer edge of the display panel 300 facing the driving part area CA, and the second ink layer 800b may be formed along the outer edge of the left side of the display panel 300. The third ink layer 800c may be formed along an outer edge of the right side of the display panel 300 to face the second ink layer 800b.

However, the embodiment is not limited thereto, and at least a portion of the first ink layer 800a, second ink layer 800b, and third ink layer 800c may be omitted.

Furthermore, the adjacent first ink layer 800a, second ink layer 800b, and third ink layer 800c can be continuously formed by being connected to each other as shown in FIG. 10, or they can be separated without being connected to each other.

Referring to FIG. 11, the ink layer 800 may include not only the outer edge 300e of the display panel 300, but also the lower plate 500, the lower protective film 400, the polarizer 200, and the adhesive layers 51, 52, 53, and 54 can be in contact while covering the side of the edge.

The ink layer 800 may include an edge positioned on the rear surface of the cover window 100 and spaced apart from the side surface of the cover window 100.

The ink layer 802 located at the inner edge of the display panel 300 may be formed along the edge of the sensing area SA, for example.

Referring to FIG. 12, the ink layer 802 may include the inner edge 300ce of the sensing area SA of the display panel 300, the lower plate 500, the lower protective film 400, and/or the polarizer 200. In addition, the adhesive layers 51, 52, 53, and 54 may cover and come into contact side surfaces of the inner edges.

The ink layer 802 may be spaced apart from the optical element 950 in a plan view.

The ink layer 802 may include an edge positioned on a rear surface of the cover window 100 and spaced apart from a side surface of the cover window 100.

The ink layers 800 and 802 may be conductive or insulating non-conductors, and may include colorants or pigments.

If the ink layers 800 and 802 may be conductive, the resistance may be greater than about 1 ohm.

The ink layers 800 and 802 may include, for example, a conductive material such as silver nanowires.

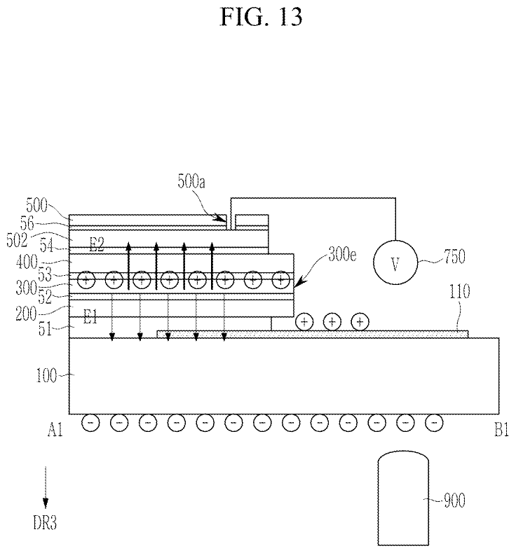

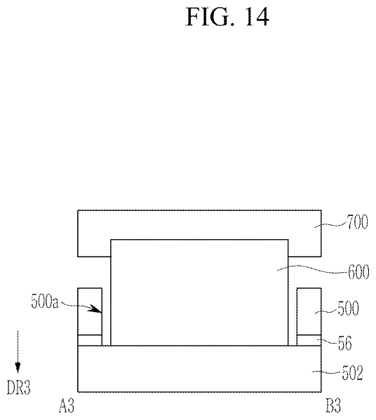

A display device according to an embodiment will be described with reference to FIG. 13 and FIG. 14 together with the previously described drawings.

FIG. 13 is a schematic cross-sectional view of the display device shown in FIG. 2 taken along line A1-B1, and FIG. 14 is a schematic cross-sectional view of the display device shown in FIG. 2 taken along line A3-B3.

Referring to FIG. 13 and FIG. 14, the display device according to an embodiment may be distinguishable from the display device 1000 described above at least in that a first plate 502 positioned between the lower plate 500 and the lower protective film 400 may further include an adhesive layer 56 between the first plate 502 and the lower plate 500.

The first plate 502 may be conductive and may include, for example, various metals or metal alloys.

The driving part 700 may be electrically connected to the first plate 502 through the conductive adhesive layer 600, and the voltage application part 750 located in the driving part 700 may be connected to the conductive adhesive layer 600 and electrically connected.

To electrically connect the driving part 700 and the first plate 502, the lower plate 500 and the adhesive layer 56 may have an opening 500a exposing the first plate 502.

The conductive adhesive layer 600 may be located in the opening 500a.

The compensation voltage described above may be applied to the first plate 502 instead of the lower plate 500 to alleviate the intensity of an electric field affecting the transistors of the display panel 300.

Depending on embodiments, the display device according to an embodiment illustrated in FIG. 13 and FIG. 14 may further include ink layers 800 and 802 located on inner or outer edges of the display panel 300 as described above.

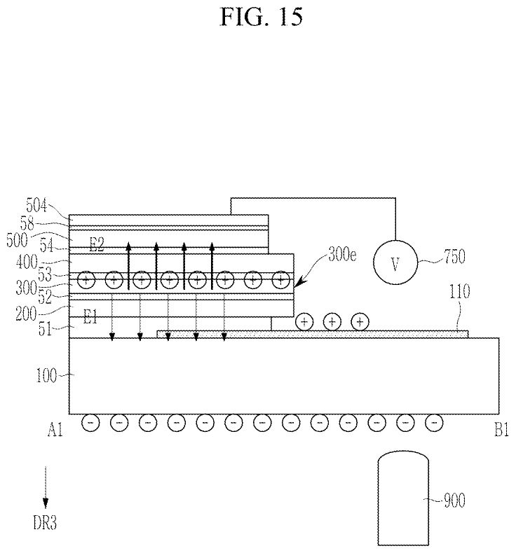

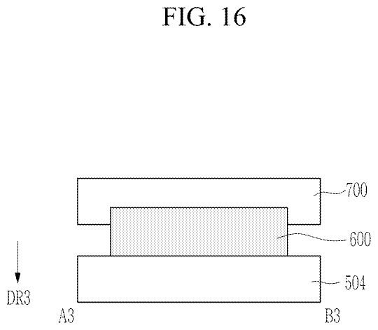

A display device according to an embodiment will be described with reference to FIG. 15 and FIG. 16 together with the previously described drawings.

FIG. 15 is a schematic cross-sectional view of the display device shown in FIG. 2 taken along line A1-B1, and FIG. 16 is a schematic cross-sectional view of the display device shown in FIG. 2 taken along line A3-B3.

Referring to FIG. 15 and FIG. 16, the display device according to an embodiment may be distinguishable from the display device 1000 described above at least in that a second plate 504 positioned outside the lower plate 500 may be further included, and an adhesive layer 58 may be further included between the second plate 504 and the lower plate 500.

The second plate 504 can be conductive and can include, for example, various metals or metal alloys.

The driving part 700 may be electrically connected to the second plate 504 through the conductive adhesive layer 600, and the voltage application part 750 located in the driving part 700 may be connected to the conductive adhesive layer 600 and electrically connected.

The compensation voltage described above may be applied to the second plate 504 instead of the lower plate 500 to alleviate the strength of the electric field affecting the transistors of the display panel 300.

Depending on embodiments, the display device according to an embodiment illustrated in FIG. 15 and FIG. 16 may further include ink layers 800 and 802 positioned on inner or outer edges of the display panel 300 as described above.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device, comprising:
a first conductive plate;
a lower protective film positioned on the first conductive plate;
a display panel positioned on the lower protective film;
a cover window located on the display panel; and
a voltage application part that applies a compensation voltage to the first conductive plate,
wherein the compensation voltage has a same polarity as charges accumulated in case that an external object rubs against an outer surface of the cover window.

2. The display device of claim 1, further comprising:
a driving part that applies a voltage to the display panel; and
a conductive adhesive layer positioned between the driving part and the first conductive plate, and electrically connecting the driving part to the first conductive plate,
wherein the voltage application part is located in the driving part.

3. The display device of claim 2, further comprising:
a wire formed in the driving part and electrically connecting the voltage application part and the conductive adhesive layer.

4. The display device of claim 2, wherein
the display panel includes a display area, a driving part area, and a bending area positioned between the display area and the driving part area,
the display panel is bent in the bending area so that the driving part area overlaps a rear surface of the display panel, and
the driving part is mounted in the driving part area and is electrically connected to the driving part.

5. The display device of claim 4, wherein the driving part includes a flexible printed circuit film, a printed circuit board, or at least one driving circuit chip.

6. The display device of claim 1, wherein a polarity of a temporal average of the compensation voltage is the same as a polarity of charges accumulated on the outer surface of the cover window.

7. The display device of claim 6, wherein an absolute value of the temporal average of the compensation voltage is greater than or equal to an absolute value of a potential of charges accumulated on an outer surface of the cover window.

8. The display device of claim 6, wherein the compensation voltage is constant.

9. The display device of claim 6, wherein the compensation voltage swings between two voltages.

10. The display device of claim 1, wherein an adhesive layer is disposed between at least one of the first conductive plate and the lower protective film, between the lower protective film and the display panel, and between the display panel and the cover window.

11. The display device of claim 1, further comprising:
a polarizer positioned between the display panel and the cover window.

12. The display device of claim 1, wherein
an ink layer is positioned on an inner or outer edge of the display panel, and
the ink layer is non-conductive or has a resistance of about 1 ohm or more.

13. The display device of claim 12, further comprising:
a sensing area overlapping at least one optical element,
a display panel having an inner edge defining the sensing area, and
an ink layer including a first ink layer formed along the inner edge.

14. The display device of claim 12, wherein
the display panel has three outer edges, and
the ink layer includes a second ink layer formed along at least a part of the three outer edges.

15. The display device of claim 1, further comprising:
a second plate positioned below the first conductive plate and having an opening exposing the first conductive plate, and
a conductive adhesive layer located in the opening and electrically connected to the first conductive plate.

16. The display device of claim 1, further comprising:
a second plate positioned between the first conductive plate and the lower protective film.

17. A display device, comprising:
a first conductive plate,
a lower protective film positioned on the first conductive plate,
a display panel positioned on the lower protective film,
a cover window located on the display panel, and
a voltage applicator that applies a compensation voltage to the first conductive plate,
wherein an average of the compensation voltage is about −1 V or less.

18. The display device of claim 17, wherein
the compensation voltage is constant or swings between two voltages.

19. The display device of claim 17, further comprising:
a driving part that applies a voltage to the display panel; and
a conductive adhesive layer positioned between the driving part and the first conductive plate, and electrically connecting the driving part to the first conductive plate,
wherein a voltage application part is located in the driving part.

20. The display device of claim 19, wherein
the display panel includes a display area, a driving part area, and a bending area positioned between the display area and the driving part area,
the display panel is bent in the bending area so that the driving part area overlaps a rear surface of the display panel, and
the driving part is mounted in the driving part area and is electrically connected to the driving part.
